(19) United States
(12) Patent Application Publication
(10) Pub. No.: US 2006/0273324 A1
(43) Pub. Date: Dec. 7, 2006

(54) Light-emitting diode and process for producing the same

(76) Inventors: Makoto Asai, Aichi-ken (JP); Shiro Yamazaki, Aichi-ken (JP); Takahiro Kozawa, Aichi-ken (JP); Mitsuhisa Narukawa, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 10/566,211

(22) PCT Filed: Jul. 26, 2004
(86) PCT No.: PCT/JP04/10635

§ 371 Date: Mar. 8, 2006

(30) Foreign Application Priority Data
Jul. 28, 2003 (JP) 2003-202240
Apr. 7, 2004 (JP) 2004-112796

(51) Int. Cl. H01L 21/00; H01L 33/00

(52) U.S. Cl. 257/79; 438/30

(57) ABSTRACT

The back surface of a semiconductor crystal substrate 102 which has a thickness of about 150 μm and is made of undoped GaN bulk crystal consists of a polished plane 102a which is flattened through dry-etching and a grinded plane 102b which is formed in a taper shape and is flattened through dry-etching. On about 10 nm in thickness of GaN n-type clad layer (low carrier concentration layer) 104, about 2 nm in thickness of Al_{0.005}In_{0.045}Ga_{0.95}N well layer 51 and about 18 nm in thickness of Al_{0.12}Ga_{0.88}N barrier layer 52 are deposited alternately as an active layer 105 which emits ultraviolet light and has MQW structure comprising 5 layers in total. Before forming a negative electrode (n-electrode c) on the polished plane of the semiconductor substrate a, the polished plane is dry-etched.

### TECHNICAL FIELD

The present invention relates to structure of a light-emitting diode and a method for fabricating the same. More particularly, the present invention deeply relates to external quantum efficiency and luminous extracting efficiency.

Accordingly, the present invention is useful for a LED (light-emitting diode) which has shorter luminous wavelength and emits blue-violet, violet, or ultraviolet light and for a method for fabricating the same.

Also, the present invention relates to a method for forming an electrode on a grinded plane of a semiconductor substrate comprising a conductive Group III nitride compound semiconductor which has already been polished.

The present invention can be widely applied to a semiconductor device in which an electrode is formed directly on its semiconductor substrate. The semiconductor device having such structure may comprise a light-emitting semiconductor device such as a semiconductor laser (LD), a light-emitting diode (LED) and also a light-receiving device and a pressure sensor. Concrete function and structure of those semiconductor devices may not be restricted by applying the present invention, so the present invention can be applied to remarkably large field.

### BACKGROUND ART

The non-patent document 1 listed below discloses general technique with respect to external quantum efficiency and luminous extracting efficiency of a light-emitting diode such as a white-light-emitting diode and a visible light-emitting diode.

The patent document 1 listed below also discloses a light-emitting diode which comprises a square pyramid taper part formed at the side of an n-type semiconductor substrate. By forming such taper part, luminous extracting efficiency improves.

Generally, in a process to manufacture a light-emitting diode, a crystal growth substrate on which an electrode and an objective semiconductor layer are formed is treated through crystal growth and then processed by such as grinding from the back surface until its thickness becomes proper to divide the semiconductor wafer into each light-emitting device unit excellently. And that process is generally carried out by employing a mechanical or physical process such as polishing or dicing.

As a semiconductor device in which an electrode is formed on the back surface of the semiconductor substrate, light-emitting semiconductor devices disclosed in the patent documents 2 to 4 are well known. Such a semiconductor device comprises an n-electrode on the back surface of a conductive semiconductor substrate and a p-electrode formed on a p-type layer and facing to the n-electrode.

As shown in the patent documents 5 and 6, when a semiconductor substrate functions as a crystal growth semiconductor, thickness of the crystal growth substrate is generally about 300 μm to 800 μm. The substrate is grinded until its thickness becomes generally from 50 μm to 150 μm and divided into each chip (light-emitting device) unit. The grinding process can be carried out before or after crystal growth process of each semiconductor layer.

When the substrate is grinded to be too thin, the substrate itself becomes easy to break and the grinding process may take too much time, which is not desirable. When the substrate is too thick, it becomes difficult to divide the semiconductor wafer into each desired shape precisely and surely, which is not desirable. When the semiconductor substrate also functions as a crystal growth substrate, generally the semiconductor substrate frequently needs to be handled (transfer operation) before and after crystal growth process. Accordingly, in order that the semiconductor substrate has strength to endure that handling, the grinding process described above is usually carried out after crystal growth process.

Accordingly, the grinding process is generally carried out until thickness of the semiconductor substrate becomes possible or easy to handle or thickness of the semiconductor substrate becomes about 100 μm before dividing process in which the semiconductor wafer is divided into each chip.

[Non-patent document 1] Norihide Yamada, “Primary Technologies for High-efficiency Visible LEDs,” Applied Physics Letters Vol. 68, No. 2 (1999), pp. 0139-0145

[Patent document 1] Japanese Patent Application Laid-open No. H11-317546

[Patent document 2] Japanese Patent Application Laid-open No. 2002-261014

[Patent document 3] Japanese Patent Application Laid-open No. 2001-77476

[Patent document 4] Japanese Patent Application Laid-open No. 2001-102673

[Patent document 5] Japanese Patent Application Laid-open No. H7-131069

[Patent document 6] Japanese Patent Application Laid-open No. H11-163403

### DISCLOSURE OF THE INVENTION

Problems to be Solved

By carrying out the physical processes described above, however, about 0.1 μm to 15 μm in thickness of damaged layer whose crystal structure is disordered (hereinafter referred to as a physically damaged layer) may be consequently formed on the surface of a plane which is processed through physical conflict and impact, and the damaged layer remains thereon. Further, the inventors of the present invention carried out series of experiments including experimental production, examination, investigation, and verification experiment with respect to a light-emitting diode which emits violet-color light and comprises a GaN bulk crystal as a substrate, and invented that the physically damaged layer which is consequently formed through the processes tends to absorb or diffuse light having comparatively shorter luminous wavelength, or less than 470 nm (e.g., blue-violet light, violet light, or ultraviolet light), in the device.

This problem, however, cannot be exposed or obvious when the inventors of the present invention examined an LED emitting blue-color light or green-color light whose peak luminous wavelength is 470 nm or more in similar experiments.

Generally, using a GaN for forming a crystal growth substrate is useful to correspond or resemble physical characteristics such as lattice constant to that of the n-type contact layer. Because the AlN substrate has comparatively larger band gap, it is useful that light once emitted from the emission layer may hardly be absorbed again.

When an AlGaN group free-standing crystal (hereinafter referred to as a bulk crystal) is used as the crystal growth substrate, however, large amount of light outputted form the emission layer (active layer) leaks into the substrate because difference of refractive indexes between the substrate and the semiconductor crystal growth layer which decides characteristics of the device is too small. Accordingly, it becomes more important to recover that light effectively and to extract light to the luminous extracting side effectively when the substrate is made of material such as a GaN bulk crystal. In short, that may become an important problem to be solved in order to improve external quantum efficiency and luminous extracting efficiency of the device especially when a light-emitting diode comprising a AlGaN group crystal growth substrate such as a GaN substrate and having comparatively shorter luminous wavelength is manufactured.

When grains in slurry (abrasives) employed in the polishing treatment are coarse, the polished plane tends to become rough or a damaged layer tends to be formed beneath the polished plane. Crystallinity of the damaged layer is deteriorated owing to friction and pressure applied during the polishing treatment. Thickness of the damaged layer may depend on each condition of slurry, frictional force, and pressure, but the inventors of the present invention conducted some experiments and found that the damaged layer may generally have thickness from 0.1 μm to 10 μm.

FIGS. 4A and 4B show sectional views of the damaged layer which is produced through such polishing treatment. The polishing treatment is carried out by using slurry each of whose grain is 9 μm. FIG. 4A is an image observed through a scanning electron microscopy (SEM image) and FIG. 4B is a monochrome image through an electron beam luminescence (CL image). As shown in FIGS. 4A and 4B, 1 μm or more in thickness of the damaged layer with deteriorated crystallinity is formed below the polished plane.

The damaged layer becomes an obstacle to improve contact between the polished plane and an electrode deposited afterward, and interference of the damaged layer prevents from obtaining excellent ohmic contact. That results in unnecessarily raising driving voltage of the semiconductor device.

In order to smooth the polished plane or to form the damaged layer which tends to be formed during polishing treatment thinner, it is preferable to reduce each amount of slurry, frictional force, and pressure in polishing treatment. Actually, however, reducing each amount of slurry, frictional force, and pressure in polishing treatment may take too much time to carry out polishing treatment, and that cannot be a practical way to produce industrial products.

The present invention has been accomplished in an attempt to solve the aforementioned problems, and an object of the present invention is to provide higher external quantum efficiency and higher luminous extracting efficiency of a light-emitting diode (LED) which comprises a bulk crystal such as GaN as a crystal growth substrate and has comparatively shorter luminous wavelength.

Anther object of the present invention is to reduce driving voltage of a semiconductor device effectively.

Further, another object of the present invention is to reduce the time of polishing treatment as much as possible.

Here, each object listed above may be enough to be fulfilled individually by at least one of each method described above, and each invention in the present application is not necessarily secure that there is a solution which solves all the problems at once.

Means to Solve the Problems

In order to solve the above-described problems, the following methods may be effective.

That is, the invention drawn to a first feature provides a method for fabricating a light-emitting diode of a surface emitting type in which a semiconductor layer is deposited on a crystal growth plane of a crystal growth substrate, comprising steps of: a shaping process for forming at least one of an output plane and a reflection plane which contributes to luminous output of the device through polishing treatment, dicing treatment, and blasting treatment from the back surface of the crystal growth substrate; and a finishing process for finishing at least one of the output plane and the reflection plane by further carrying out etching treatment.

Here, depth of the etching treatment may preferably be in a range from 0.1 μm to 15 μm, and further preferably in a range from 0.2 μm to 8 μm. Further preferably, depth of etching may be in a range 1 μm to 7 μm. The crystal growth substrate may be made of a well-known material.

The invention drawn to a second feature is that the shaping process comprises a taper part forming process for forming a taper plane, which inclines to the crystal growth plane of the crystal growth substrate, at least as a portion of the output plane or at least as a portion of the reflection plane.

The invention drawn to a third feature is that at least a portion of the taper part forming process comprises a process for forming an approximately V-shaped dividing groove which divides a semiconductor wafer comprising plural light-emitting diodes into each light-emitting diode.

The invention drawn to a fourth feature is that the peak luminous wavelength of the light-emitting diode is less than 470 nm.

The invention drawn to a fifth feature is that the crystal growth substrate is formed by using AlₓGa₁₋ₓN (0≦x≦1) or silicon carbide (SiC).

The invention drawn to a sixth feature provides a light-emitting diode of a surface emitting type in which a semiconductor layer is deposited on a crystal growth plane of a crystal growth substrate, wherein the crystal growth substrate comprises at least one of an output plane and a reflection plane which contributes to luminous output of the device through a physical forming process such as polishing treatment, dicing treatment, and blasting treatment, and a physically damaged layer which is formed on the surface of at least one of the output plane and the reflection plane and remains owing to friction and shock generated in the shaping process is removed.

The invention drawn to a seventh feature is that a metal layer which has light-transparency to transmit light to the luminous extracting side of the device is formed on the output plane.

The invention drawn to an eighth feature is that a metal layer which reflects light to the luminous extracting side of the device is formed on the reflection plane.

The invention drawn to a ninth feature is that the crystal growth substrate is formed by using AlₓGa₁₋ₓN (0≦x≦1) or silicon carbide (SiC).

The invention drawn to a tenth feature is that a taper plane which inclines to the crystal growth plane of the crystal growth substrate is formed at least as a portion of the output plane and at least as a portion of the reflection plane.

The invention drawn to an eleventh feature provides a light-emitting diode of a surface emitting type in which a semiconductor layer is deposited on a crystal growth plane of a crystal growth substrate, comprising a taper plane which inclines to the crystal growth plane of the crystal growth substrate which is formed at least at a portion of the sidewall of the light-emitting diode, wherein the taper plane is exposed to the surface side of the light-emitting diode at which a semiconductor crystal layer and a positive electrode are formed, and a physically damaged layer which is formed on the surface of the taper plane and remains owing to friction and shock generated in the taper part forming process is removed.

The invention drawn to a twelfth feature provides a light-emitting diode which is fabricated by dividing a semiconductor wafer comprising plural light-emitting diodes into each light-emitting diode, comprising a taper plane at least at a portion of the sidewall of the light-emitting diode, wherein the taper plane is a portion of the plane of an approximately V-shaped dividing groove which divides the semiconductor wafer into each light-emitting diode.

The invention drawn to a thirteenth feature is that the peak luminous wavelength of the light-emitting diode is less than 470 nm.

The invention drawn to a fourteenth feature is to carry out dry-etching treatment to a polished plane of a semiconductor substrate which is already polished and comprises a Group III nitride compound semiconductor before electrode forming process for forming an electrode on the polished plane of the semiconductor substrate.

As used herein, the term “Group III nitride compound semiconductor” generally refers to a binary, ternary, or quaternary semiconductor having arbitrary compound crystal proportions and represented by Al_{1-x-y}Ga_{y}InₓN (0≦x≦1, 0≦y≦1, 0≦1-x-y≦1). A semiconductor doped with p-type or n-type impurity is also included in a Group III nitride compound semiconductor described in the present specification.

The expression “Group III nitride compound semiconductor” encompasses semiconductors in which the aforementioned Group III element (Al, Ga, or In) is partially substituted by boron (B) or thallium (Tl), or in which nitrogen (N) is partially substituted by phosphorus (P), arsenic (As), antimony (Sb), or bismuth (Bi).

As the aforementioned p-type impurity (acceptor), a well-known p-type impurity such as magnesium (Mg) and calcium (Ca) may be used.

As the aforementioned n-type impurity (donor), a well-known n-type impurity such as silicon (Si), sulfur (S), selenium (Se), tellurium (Te), and germanium (Ge) may be used.

These impurities (acceptor or donor) may be incorporated in combination of two or more species, and both a p-type impurity and an n-type impurity may be incorporated in combination.

Accordingly, by dry-etching the polished plane before forming the electrode thereon, the damaged layer having deteriorated crystallinity can be removed and the surface of the polished plane becomes comparatively smooth. That enables to obtain excellent ohmic contact. That may be because the damaged layer has higher resistivity owing to its deteriorated crystallinity.

Through employment of the aforementioned features of the present invention, driving voltage of the semiconductor device can be reduced effectively.

In the present invention, dry-etching is carried out by using RIE equipment and ICP equipment in order to etch only a predetermined plane selectively.

According to the features described above, it is not especially required to dimension of grains of slurry, each amount of frictional force and pressure in polishing treatment, which enables to reduce polishing time of the semiconductor substrate. Accordingly, by employing the method of the present invention, productivity of the semiconductor device can be improved.

The invention drawn to a fifteenth feature is to form the semiconductor substrate by using an n-type AlₓGal₁₋ₓN (0≦x≦1).

FIG. 5 is a graph showing the relationship between a depth D of dry-etching the polished plane of the semiconductor substrate comprising a gallium nitride (n-type GaN) which is doped with Si at concentration of 4×10¹⁸/cm³ and ohmic characteristic of the device. By varying the depth D of dry-etching to 0 μm, 1 μm, and 4 μm, voltage and electric current characteristic of the device is measured.

Measurement is carried out as shown in FIGS. 6 and 7. An n-electrode c is formed the polished plane of a semiconductor substrate a through deposition. A crystal growth layer b may be formed to have arbitrary structure according to structure of a desired semiconductor device. An arbitrary crystal growth method may be employed to grow the crystal growth layer b. FIG. 7 illustrates that a damaged layer a1 is removed through dry-etching treatment. The distance between two n-electrodes c shown in FIGS. 6 and 7 is about 100 μm, respectively. A measuring equipment y comprises a direct current power source of variable voltage, a voltage measuring apparatus and an electric current measuring apparatus, which are abbreviated in FIGS. 6 and 7.

FIG. 5 shows result of measuring electric current and voltage after carrying out polishing treatment using about 9 μm of grains of slurry. As shown in the graph of FIG. 5, ohmic characteristic of the n-electrode c becomes remarkably bad when dry-etching is not carried out. When the light-emitting semiconductor device is manufactured according to the first feature described above, the semiconductor substrate may be preferably formed by using an n-type AlₓGa₁₋ₓN (0≦x≦1) as shown in FIGS. 5, 6, and 7. In other words, the method of the second feature of the present invention is very preferable for at least forming the electrode on the back surface of the substrate of the light-emitting semiconductor device.

Especially, when the semiconductor substrate a is formed by using a semiconductor comprising AlₓGa₁₋ₓN (x≈0) which is doped with an n-type impurity such as Si, or by using an n-type gallium nitride, physical conditions such as hardness, lattice constant, crystallinity, and electrical conduction characteristic may be desirable. That enables the semiconductor substrate to function excellently as a semiconductor crystal growth substrate and an n-type contact layer, which is very desirable.

The invention drawn to a sixteenth feature is that depth of removing the polished plane through dry-etching treatment is in a range from 0.1 μm to 15 μm.

Although it depends on each condition of grains of slurry, frictional force and pressure, the device of the present invention may function effectively at the depth disclosed in the sixteenth feature of the present invention. When the depth of removing the polished plane is too large, dry-etching treatment takes too much time, which is not desirable. When the depth of removing the polished plane is too small, effect for carrying out dry-etching treatment is inadequate and excellent ohmic contact cannot be obtained, which is not desirable. Also, when the depth of removing the polished plane is too small, it becomes necessary to reduce radius of grain of slurry, each amount of frictional force and pressure in order to obtain certain degree of excellent ohmic contact. That requires too much time to carry out polishing treatment, which is not desirable.

The invention drawn to a seventeenth feature is that depth of removing the polished plane through dry-etching treatment is in a range from 0.2 μm to 8 μm.

Although it depends on each condition of slurry, frictional force, pressure, and composition ratio of the substrate, optional depth of dry-etching the polished plane may be within the range disclosed in the seventeenth feature of the present invention. That is, when the depth of dry-etching the polished plane is in that range, both polishing treatment and dry-etching treatment can be carried out in their minimum time and optimum ohmic characteristic can be obtained between the semiconductor substrate and the electrode.

Through employment of the aforementioned features of the present invention, the aforementioned drawbacks can be overcome effectively and rationally.

### EFFECTS OF THE INVENTION

Effects to be obtained by the present invention are as follows.

That is, according to the first feature of the present invention, when an objective shaping process is carried out through mechanical or physical treatments such as polishing, dicing, and blasting treatments, the physically damaged layer left on the surface of at least one of the output plane and the reflection plane (hereinafter referred to as a physically processed plane or simply a processed plane) can be removed effectively through etching treatment. As a result, light absorption or diffusion of light toward inside of the device caused by the physically damaged layer formed on the processed plane (: the output plane or the reflection plane) can be restrained effectively. Accordingly, external quantum efficiency and luminous extracting efficiency can be improved when the light-emitting diode (LED) is manufactured.

According to the second feature of the present invention, because amount of light absorbed by the sidewalls of the light-emitting diode or diffused in the diode increases owing to the method of the first feature of the present invention, external quantum efficiency and luminous extracting efficiency of the light-emitting diode can be improved effectively.

Also, by carrying out the taper part forming process during the shaping process, not only the taper part but also the physically processed plane including the taper part can be etched at one time. In short, the finishing process for etching the processed plane can be carried out along with etching the taper part.

According to the third feature of the present invention, at least a portion of the taper part forming process can be carried out by carrying out the process for forming the dividing groove. Alternatively, the process for forming the dividing groove may take place of the whole process for forming the taper part. As a result, the taper part forming process can be carried out quite effectively according to the third feature of the present invention.

Especially, each feature of the present invention described above may function effectively with respect to a light-emitting diode at least a portion of whose luminous emission is in a frequency range whose luminous spectrum is at least less than 470 nm. According to the fourth and thirteenth aspects of the present invention, however, large amount of light whose luminous spectrum is less than 470 nm in a frequency range of the objective luminous spectrum of the light-emitting diode may not have bad influence, or absorption of light or diffusion of light in the device, owing to the physically damaged layer. As a result, according to the fourth and thirteenth aspects of the present invention, a light-emitting diode with high luminous efficiency, in which possibility of reducing external quantum efficiency owing to the physically damaged layer is effectively excluded, can be provided.

Here, the threshold of the luminous spectrum (470 nm) is determined from some experience as described above. Also, this threshold may partially depend on degree of damage (depth of roughness) of the physically damaged layer, material and characteristic of the semiconductor crystal (a growth layer or a semiconductor bulk crystal substrate), and so on. Degree of damage or depth of roughness of the physically damaged layer may depend on material and diameter of a grain of slurry used in the polishing treatment, material, diameter of a grain, momentum and flow rate of slurry used in the blasting treatment, and so on. Even considering all those condition, however, the present invention is found to be effective at least under the scope described above.

The crystal growth substrate of the present invention can be made of well-known and arbitrary materials. Alternatively, considering device characteristics such as luminous extracting efficiency with respect to refraction index and light transparency, the crystal growth substrate may preferably be made of semiconductor bulk crystal such as an AlGaN group composition or a SiC group composition in order to improve luminous output of the light-emitting diode as much as possible (the fifth and the ninth features of the present invention). Effect of the present invention becomes more remarkable when the substrate is made of a material which has comparatively good characteristic with respect to luminous extracting efficiency as described above.

Especially, using a GaN for forming a crystal growth substrate is useful to correspond or resemble physical characteristics such as lattice constant to those of the n-type contact layer. Because the AlN substrate has comparatively larger band gap, the light once emitted from the emission layer may hardly be absorbed again in AlN, and that is desirable. Here, aluminum composition x of AlₓGa₁₋ₓN (0≦x≦1) functions as an adjustable parameter which is very optimum to select, add, or weight superiority of each condition (the fifth and the ninth features of the present invention).

According to the sixth feature of the present invention, because the physically damaged layer is removed, absorption of light (or diffusion of light to inside of the device) owing to the physically damaged layer can be restrained effectively. That is, according to the sixth feature of the present invention, an objective light-emitting diode (LED) can obtain higher external quantum efficiency and higher luminous extracting efficiency.

According to the seventh feature of the present invention, a metal layer which has light-transparency to transmit light to the luminous extracting side of the device is formed on the output plane. As a result, absorption of light at the light-transparent plane can be reduced and luminous transparency around the metal layer is improved. That results in improving external quantum efficiency and luminous extracting efficiency of the device.

According to the eighth feature of the present invention, a metal layer which reflects light is formed on the reflection plane. As a result, absorption of light at the reflection plane can be reduced and reflectivity of the reflection plane can be improved. That results in improving external quantum efficiency and luminous extracting efficiency of the device.

According to the tenth feature of the present invention, quantity of light which is absorbed at the sidewalls of the light-emitting diode or is diffused in the light-emitting diode can be reduced effectively and the reflected light can be outputted to the luminous extracting side very effectively. As a result, external quantum efficiency and luminous extracting efficiency of the device can be improved.

According to the eleventh feature of the present invention, the taper plane is exposed to the surface of the device. That enables to improve external quantum efficiency and luminous extracting efficiency of the light-emitting diode effectively when light radiated from the taper plane is outputted directly to the surface of the light-emitting diode.

And the taper plane can be formed by using a portion of the plane comprising a dividing groove which is formed on the surface of the device (the twelfth feature of the present invention). At that time, any particular process for forming a taper part is not needed, and that is very desirable.

According to the thirteenth feature of the present invention, the polished plane for forming the electrode is dry-etched and then the electrode is formed on the etched plane. Because the damaged layer can be removed through polishing treatment, ohmic characteristic of the electrode toward the polished plane can be improved.

According to the fourteenth feature of the present invention, when the semiconductor substrate is made of an n-type AlₓGa₁₋ₓN (0≦x≦1), ohmic characteristic of the electrode can be remarkably improved by carrying out dry-etching treatment on the polished plane before forming the electrode thereon.

According to the fifteenth feature of the present invention, when the depth of dry-etching, or the thickness of the polished plane to be removed, is in a range from 0.1 μm to 15 μm, time for the polishing process and the dry-etching process can be kept the minimum and ohmic characteristic of the electrode can be improved maximally.

### BRIEF DESCRIPTION OF THE DRAWINGS

FIG. 1 is a sectional view of a face-down type light-emitting diode 100 according to a first embodiment of the present invention.

FIG. 2 is a sectional view of a face-up type light-emitting diode 200 according to a second embodiment of the present invention.

FIG. 3 is a sectional view of a face-up type light-emitting diode 1000 according to a third embodiment of the present invention.

FIGS. 4A and 4B are photos of sectional planes of damaged layers generated through a grinding process.

FIG. 5 is a graph showing the relationship between ohmic characteristic and a depth of dry-etching a grinded plane.

FIG. 6 is a schematic view of a circuit for measuring ohmic characteristic of the face-up type light-emitting diode 200 shown in FIG. 2.

FIG. 7 is a schematic view of a circuit for measuring ohmic characteristic of the face-up type light-emitting diode 200 shown in FIG. 2.

FIG. 8 is a sectional view of a light-emitting diode 500 according to the embodiment of the present invention.

FIG. 9 is a table showing each driving voltage VF of the light-emitting diode 500 according to the embodiment and a light-emitting diode 500′ according to a modified embodiment of the present invention.

FIGS. 10A-10C are views illustrating each process for fabricating the light-emitting diode according to other embodiment of the present invention.

### BEST MODE FOR CARRYING OUT THE INVENTION

The present invention can show excellent actions and effects under the following conditions.

For example, the depth of etching may preferably be in a range from 0.1 μm to 15 μm, and more preferably from 0.2 μm to 8 μm. And because the damaged layer has a thickness of 1 μm or more, the depth of etching may more preferably be in a range from 1 μm to 7 μm. When the depth of etching is too small, a physically damaged layer often tend not to be removed sufficiently. When the depth of etching is too large, too much time is needed for the etching treatment and it is undesirable in productivity and production cost. That is, according to this appropriate range of the depth of etching, the physically damaged layer remaining on a plane which is etched physically can be removed sufficiently to the required content.

More preferably, suitable and optimum depth of etching may be determined according to actual and physical conditions of shaping. For example, although the required and sufficient depth of etching depends on each condition such as a size of slurry, pressure of the process plane in a grinding process and its processing speed, the appropriate depth of etching may be determined experientially without any particular trial-and-error process. That can be applied to other mechanical shaping processes such as dicing and blasting.

Materials for forming the crystal growth substrate and impurities doped into it are already described above.

Especially, the crystal growth substrate made of GaN is useful, for example, for each physical characteristic such as lattice constant to match or to correspond to that of the n-type contact layer. Also, the AlN substrate is useful because it hardly absorbs the light emitted again owing to its comparatively larger bandgap. In order to select, add, or weight each advantage or usefulness properly, aluminum composition ratio x in the composition formula AlₓGa₁₋ₓN (0≦x≦1) can be a very optimum adjustable parameter. And especially when an LED which emits light having very short wavelength is manufactured, bandgap, or aluminum composition ratio x, of each semiconductor crystal layer of the LED may preferably be as large as possible, as long as it does not affect other characteristics in the LED.

Alternatively, the active layer (the emission layer) in the light-emitting diode may have arbitrary structure. It may have MQW structure, SQW structure, or single-layer structure which does not have quantum-well structure.

Embodiments of the present invention will next be described based on concrete examples. The scope of the present invention, however, is not limited to the embodiment described below.

### Embodiment 1

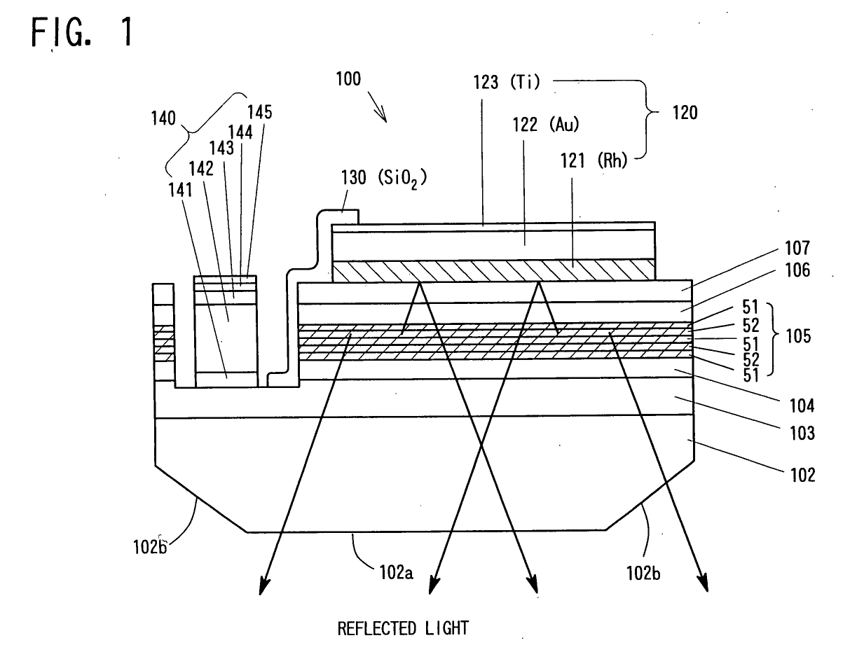

FIG. 1 is a sectional view of a face-down type light-emitting diode 100 of the present embodiment. The back surface of a semiconductor crystal substrate 102 which has a thickness of about 150 μm and is made of undoped GaN bulk crystal comprises a polished plane 102a which is flattened through dry-etching and a polished plane 102b which is formed in a taper shape and is flattened through dry-etching. As a crystal growth plane which is almost parallel to the polished plane 102a of the semiconductor crystal substrate 102, c plane of the GaN bulk crystal is applied. About 4.0 μm in thickness of silicon (Si) doped gallium nitride (GaN) n-type contact layer 103 is deposited through crystal growth on the crystal growth plane.

The n-type contact layer 103 has an impurity (Si) concentration of about 1×10¹⁹/cm³. About 10 nm in thickness of GaN n-type clad layer (low carrier concentration layer) 104 is formed on the n-type contact layer 103.

On the n-type clad layer 104, about 2 nm in thickness of Al_{0.005}In_{0.045}Ga_{0.95}N well layer 51 and about 18 nm in thickness of Al_{0.12}Ga_{0.88}N barrier layer 52 are deposited alternately as an active layer 105 which emits ultraviolet light and has MQW structure comprising 5 layers in total. About 50 nm in thickness of p-type clad layer 106 made of Mg-doped p-type Al_{0.15}Ga_{0.85}N is formed on the active layer 105. About 100 nm in thickness of p-type contact layer 107 made of Mg-doped p-type GaN is formed on the p-type clad layer 106.

On the p-type contact layer 107, a positive electrode 120 having multiple-layer structure is formed through metal deposition, and a negative electrode 140 is formed on the n-type contact layer 103 having high-carrier concentration. The positive electrode 120 having multiple-layer structure comprises 3 layers in total, or a first layer 121 of the positive electrode which contacts to the p-type contact layer 107, a second layer 122 of the positive electrode formed on the first layer 121 of the positive electrode, and a third layer 123 of the positive electrode formed on the upper portion of the second layer 122 of the positive electrode.

The first layer 121 of the positive electrode is about 0.1 μm in thickness of metal layer which is made of rhodium (Rh) and contacts to the p-type contact layer 107. The second layer 122 of the positive electrode is about 1.2 μm in thickness of metal layer made of gold (Au). The third layer 123 of the positive electrode is about 20 Å in thickness of metal layer made of titanium (Ti).

The negative electrode 140 having multiple-layer structure comprises about 175 Å in thickness of vanadium (V) layer 141, about 1000 Å in thickness of aluminum (Al) layer 142, about 500 Å in thickness of vanadium (V) layer 143, about 5000 Å in thickness of nickel (Ni) layer 144, and about 8000 Å in thickness of gold (Au) layer 145 deposited in sequence on the exposed portion of the n-type contact layer 103.

Between the thus-obtained positive electrode 120 and the negative electrode 140, a protection film 130 made of SiO₂ film is formed. The protection film 130 covers a portion of the n-type contact layer 103 which is exposed to form the negative electrode 140, the sidewall of the active layer 105 which is exposed through etching treatment, the exposed sidewall of the p-type clad layer 106, the exposed sidewall and a portion of the upper surface of the p-type contact layer 107, the sidewall of the first layer 121 of the positive electrode, the sidewall of the second layer 122 of the positive electrode, and the sidewall and a portion of the third layer 123 of the positive electrode. Thickness of the SiO₂ protection film 130 covering the third layer 123 of the positive electrode is 0.5 μm.

Next, a method for manufacturing the light-emitting diode 10 is explained hereinafter.

The light-emitting diode 10 of the present invention was produced through metal-organic vapor phase epitaxy (hereinafter called “MOVPE”). The following gasses were employed: ammonia (NH₃), carrier gas (H₂ or N₂), trimethylgallium (Ga(CH₃)₃, hereinafter called “TMG”), trimethylaluminum (Al(CH₃)₃, hereinafter called “TMA”), trimethylindium (In(CH₃)₃, hereinafter called “TMI”), and cyclopentadienylmagnesium (Mg(C₅H₅)₂, hereinafter called “Cp₂Mg”).

The undoped GaN bulk crystal semiconductor crystal substrate 102 was placed on a susceptor in a reaction chamber for the MOVPE treatment after its main surface ‘c’ was cleaned by an organic washing solvent and heat treatment. Thickness of the semiconductor crystal substrate 102 was about 400 μm. Then the semiconductor crystal substrate 102 was baked at about 1150° C. under H₂ vapor fed into the chamber under normal atmospheric pressure.

(Growth of the N-Type Contact Layer 103)

About 4.0 μm in thickness of GaN n-type contact layer 103 having electron concentration of 2×10¹⁸/cm³ and Si concentration of 1×10¹⁹/cm³ was formed under conditions controlled by keeping the temperature of the semiconductor crystal substrate 102 at 1150° C., and concurrently supplying H₂, NH₃, TMG and dilute silane.

(Growth of the N-Type Clad Layer 104)

About 10 nm in thickness of GaN n-type clad layer 104 (low carrier concentration layer) was formed under conditions controlled by keeping the temperature of the semiconductor crystal substrate 102 at 1150° C., and concurrently supplying H₂, NH₃, and TMG.

(Growth of the Active Layer 105)

After forming the n-type clad layer 104, the active layer of MQW structure, comprising 5 layers in total, is formed.

First, about 2 nm in thickness of Al_{0.005}In_{0.045}Ga_{0.95}N well layer 51 was formed on the n-type clad layer 104 under conditions controlled by lowering the temperature of the semiconductor crystal substrate 102 to 770° C., changing carrier gas from H₂ to N₂, keeping the supplying amount of the carrier gas N₂ and NH₃, and concurrently supplying TMG, TMI, and TMA.

Next, about 18 nm in thickness of Al_{0.12}Ga_{0.88}N barrier layer 52 was formed on the well layer 51 under conditions controlled by concurrently supplying N₂, NH₃, TMG, and TMA.

By repeating these processes, the well layer 51 and the barrier layer 52 were formed alternately and the active layer 105 comprising 5 layers in total (the well layer 51, the barrier layer 52, the well layer 51, the barrier layer 52, and the last well layer 51) was obtained.

(Crystal Growth of the P-Type Clad Layer 106)

Then magnesium (Mg) doped p-type Al_{0.15}Ga_{0.85}N having thickness of about 20 nm and Mg concentration of 5×10¹⁹/cm³ was formed as a p-type clad layer 106 under conditions controlled by raising the temperature of the semiconductor crystal substrate 102 to 890° C. and concurrently supplying N₂, TMG, TMA, and CP₂Mg.

(Crystal Growth of the P-Type Contact Layer 107)

Then Mg-doped p-type GaN having thickness of about 85 nm and Mg concentration of 5×10¹⁹/cm³ was formed as a p-type contact layer 107 under conditions controlled by raising the temperature of the semiconductor crystal substrate 102 to 1000° C., changing the carrier gas to H₂ again, and concurrently supplying H₂, NH₃, TMG, and CP₂Mg.

The processes described above are the crystal growth process of each semiconductor layer comprising a Group III nitride compound semiconductor.

(Forming the Positive Electrode 120)

A photoresist layer was then formed on the surface of the wafer. The portion of the photoresist layer above the electrode forming part of the p-type contact layer 107 was then removed by patterning using photolithography to form a window. In short, only a portion of the p-type contact layer 107 for forming the positive electrode 120 was exposed. After establishing a high vacuum of less than 10⁻⁴ Pa vacuum order, about 0.1 μm in thickness of positive electrode first layer 121 made of rhodium (Rh), about 1.2 μm in thickness of positive electrode second layer 122 made of gold (Au), and about 20 Å in thickness of positive electrode third layer 123 made of titanium (Ti) were deposited in sequence on the exposed portion of the p-type contact layer 107. The sample was then removed from the vacuum evaporation equipment and each metal layer laminated on the photoresist layer were removed by a lift-off process.

Then the negative electrode 140 and the protection film 130 were formed according to each process for forming the conventional and well-known face-down type light-emitting diode.

(Alloying Treatment)

Next, the chamber in which the resultant sample was placed was evacuated by use of a vacuum pump, and subsequently O₂ gas was fed to the chamber, to thereby regulate the pressure of the chamber to 3 Pa. Thereafter, the temperature of the chamber was maintained at about 550° C., and the sample was heated for about three minutes, to thereby lower the resistances of the p-type contact layer 107 and the p-type clad layer 106, as well as to perform alloying of the contact layer 107 and the positive electrode 120 and alloying of the n-type contact layer 103 and the negative electrode 140. Thus, the electrodes can be connected to each semiconductor layer on which both the positive and the negative electrodes were deposited more firmly.

(Polishing Treatment)

Next, a protection film which protects each electrode and each deposited semiconductor layer from pressure and impact during polishing treatment was formed on the surface (face plane) of the wafer, and the wafer was pasted on a wafer pasting board of a polishing equipment. And the back surface of the semiconductor crystal substrate 102 was polished by using a polishing machine. Diameter of grains of the slurry employed in this polishing treatment was 9 μm, and the polishing treatment was carried out until thickness of the semiconductor crystal substrate 102 decreased from 400 μm to 150 μm. Then the wafer was removed from the wafer pasting board of the polishing equipment and washed to remove wax and the protection film which were used to paste the wafer.

Diameter of the grains of the slurry employed in the polishing treatment may preferably in a range from 0.5 μm to 15 μm. When the diameter of the slurry is too big, thickness of the damaged layer tends to become too large, which is not desirable. When the diameter of the grains of the slurry is too small, the polishing treatment tends to take too much time, which is not desirable. More preferably, the diameter of the grains of the slurry is in a range from 1 μm to 9 μm.

(Forming a Taper Part)

The wafer was pasted to an adhesive tape so that the electrode forming plane faced the adhesive tape. Next, a V-shaped groove was formed in cross stripes pattern per each unit on the back surface of the wafer by carrying out grinding process using a dicing cutter. Accordingly, a grinded plane 102b in a taper shape as shown in FIG. 1 can be obtained. Then the wafer was extracted from the adhesive tape.

(Etching Treatment)

Next, the back surface (the polished plane) of the semiconductor crystal substrate 102 polished in the polishing treatment was dry-etched to the depth of about 2 μm. This dry-etching treatment removed at least most of the damaged layer which was generated in the polishing treatment. Any of the following equipments can be employed in this dry-etching treatment:

(a) RIE equipment

(b) ICP equipment

The dry-etching treatment can be carried out according to the processes as follows.

(1) A protection film to RIE etching gas is formed on the surface (face plane) of the wafer by use of resin.

(2) The wafer is placed at the RIE equipment with the back surface of the wafer up.

(3) The back surface of the wafer is dry-etched in the RIE equipment.

(Conditions for Carrying Out Etching Treatment)

(a) Gas employed in the treatment: CCl₂F₂

(b) Degree of vacuum: 5.3 Pa (0.04 Torr)

Here, etching is carried out to the depth of about 0.8 μm under condition that extracting voltage (acceleration voltage) is controlled to be 800V, and dry-etching treatment is further carried out to the rest of the wafer having thickness of 0.2 μm after decreasing the extracting voltage to be 400V.

Accordingly, by carrying out etching under condition of decreasing extracting voltage (acceleration voltage) asymptotically, damaged layer formed at the back surface of the wafer through the etching treatment (a further thinner additional physically damaged layer) can be removed or reduced.

(4) And the protection film to the RIE etching gas is removed by using peeling-off liquid.

For example, the dry-etching disclosed in Japanese Patent Application Laid-open No. H8-274081 may be referred to as a standard of dry-etching treatment.

(Dividing Process)

Half cutting treatment or scribing treatment was carried out to the surface of the wafer, and the semiconductor wafer was divided into each chip through breaking process. Each of these processes may be carried out according to a well-known prior art. For example, the dividing technique disclosed in the Japanese Patent Application Laid-open No. 2001-284642 may be referred to as a standard of dividing process.

According to the processes described above, the face-down type light-emitting diode 100 shown in FIG. 1 can be obtained.

Luminous output of the thus-obtained light-emitting diode 100 is improved by about 20% compared with that of a conventional diode without carrying out the dry-etching treatment of this embodiment. And luminous output of the light-emitting diode 100 having the taper part is twice as large as that of the conventional diode without a taper part.

In short, the light-emitting diode 100 in the embodiment 1 of the present invention has remarkably high luminous output owing to multiplier effect of using GaN bulk crystal to form the crystal growth substrate, forming the taper part at the crystal growth substrate, and carrying out dry-etching treatment to the polished plane and the grinded plane of the crystal growth substrate.

### Modified Example and Each Optimum Condition

The first embodiment of the present invention can be modified or optimized according to each condition as follows.

For example, an optimum depth of dry-etching is determined according to size of the grains of the slurry used in the previous polishing process, degree of frictional force and pressure, and composition ratios of the substrate. But experience shows that the optimum depth of dry-etching may be in a range from 1 μm to 8 μm. When the depth of dry-etching is within this range, time for the grinding process and the dry-etching process can be kept to the minimum and that is desirable in productivity.

In the first embodiment, the semiconductor crystal substrate 102 is preferably made of an undoped AlₓGa₁₋ₓN (0≦x≦1). Alternatively, the semiconductor crystal substrate 102 can be made of other Group III nitride compound semiconductor and a semiconductor crystal such as SiC.

In the first embodiment, a semiconductor substrate a free-standing gallium nitride crystal (: GaN bulk crystal) is applied as the semiconductor crystal substrate 102. The semiconductor crystal substrate 102 does not necessarily have single-layer structure. For example, a semiconductor bulk crystal comprising AlₓGa₁₋ₓN (0≦x≦1) whose thickness remains in 150 μm or more after polishing and etching can be an appropriate semiconductor crystal substrate 102 to obtain the same structure as in the first embodiment. Because the upper part of the semiconductor crystal substrate 102 is removed in the grinding process until its thickness becomes 150 μm, the semiconductor crystal substrate 102 may have arbitrary structure. Alternatively, a substrate in which a base layer is formed on a silicon substrate and a GaN layer is grown thereon, or an epitaxial growth substrate, can be applied as the semiconductor crystal substrate 102. In that case, the silicon substrate and the base layer may be removed through gas etching treatment and grinding treatment to leave only the n-type AlₓGa₁₋ₓN (0≦x≦1) to have thickness of about 150 μm.

Further alternatively, thickness of the semiconductor crystal substrate 102 to be left may not be necessarily limited to 150 μm. The semiconductor crystal substrate 102 to be left may have any thickness as long as it is in a range from 50 μm to 300 μm. Thickness of the semiconductor crystal substrate 102 before carrying out the grinding process may preferably be in a range from 250 μm to 500 μm. More preferably, thickness of the semiconductor crystal substrate 102 before carrying out the grinding process may be in a range from 300 μm to 400 μm. When the thickness is too large, the grinding process takes too much time and that is not desirable. When the thickness is too small, the semiconductor wafer tends to be damaged in its handling, and that is not desirable.

### Modified Example of the First Embodiment

In the first embodiment, both of the positive electrode and the negative electrode are formed on the surface (face plane) of the semiconductor crystal substrate 102. Alternatively, the negative electrode may be formed on the back surface of the semiconductor crystal substrate 102, or a polished plane 102a which is formed to have flat plane through dry-etching and a grinded plane 102b which is formed in a taper shape through dry-etching. At that time, a face-down type light-emitting diode can be manufactured by forming the semiconductor crystal substrate 102 to be an n-type substrate having excellent electric conductivity and forming the negative electrode to be a light-transparent thin-film electrode.

In such a face-down type light-emitting diode, for example, light absorption by the physically damaged layer can be suppressed in a process that ultraviolet light is outputted from the surface of the light-transparent negative electrode. Accordingly, light can be efficiently extracted from the light-emitting diode through the light-transparent negative electrode.

In short, the light-transparent electrode can be formed on the etching treatment plane. Because the light-transparent electrode can be deposited (formed contacting) directly to the n-type substrate without using a physically damaged layer, the etching treatment of the present invention may also distribute for the electrode to maintain its excellent ohmic characteristic.

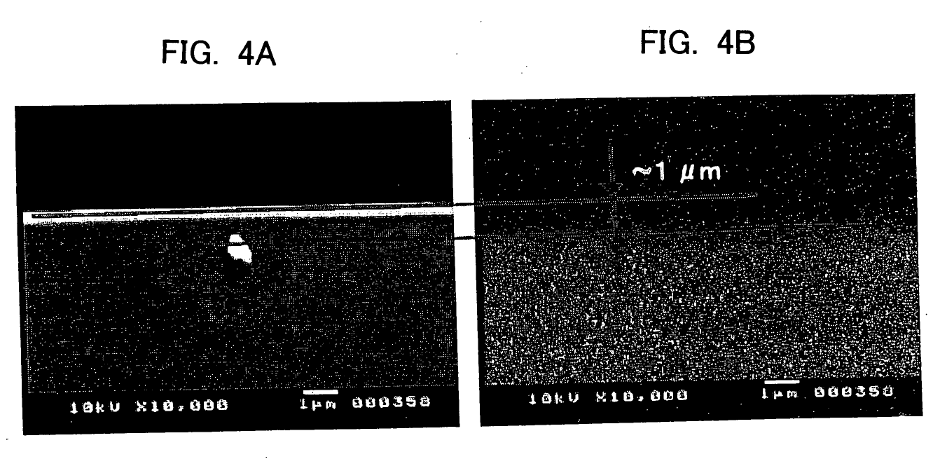

For example, in the process for manufacturing the longitudinal conduction face-down type light-emitting diode, a light-transparent thin-film electrode is formed on the back surface of the semiconductor crystal substrate 102 through vapor deposition treatment instead, of forming the negative electrode 140. This vapor deposition treatment of the light-transparent thin-film electrode may be carried out between the etching treatment and the dividing treatment described above. Wiring to the negative electrode in such light-emitting diode may be carried out by wire-bonding as shown in the above-described patent document 1 (FIGS. 1 and 4).

The present invention is also useful when the physically processed plane described above is formed and shaped through blasting treatment. In the first embodiment, the polished plane 102a which is formed almost flat through dry-etching treatment and the grinded plane 102b which is formed in a taper shape through dry-etching treatment contact with each other at each of their edge. Alternatively, the desired roundness R (roundness obtained by chamfering) can be obtained by curving the side (edge) of these planes through blasting treatment. The physically damaged layer may also be formed on the physical processing plane through such blasting treatment. By carrying out the etching treatment in the first embodiment after the blasting treatment, almost the same effect as in the first embodiment can be obtained. And carrying out appropriate blasting treatment enables to shorten necessary and adequate time for etching treatment.

Such characteristics are explained in the following second embodiment.

### Second Embodiment

In a process of forming dividing grooves by applying laser irradiation, a fused and re-solidified material, which is a material of a semiconductor fused by laser irradiation heat, and a fused, scattered and re-solidified material, which is a material fused and scattered in a chamber and then adhered and solidified there, tend to be left at the sidewalls and the back surface of the device. Such fused and re-solidified material and fused, scattered and re-solidified material may preferably be removed through blast treatment and so on considering external quantum efficiency and luminous extracting efficiency. Even by employing such blasting treatment, however, a physically damaged layer as in the first embodiment may be formed owing to some conditions of the treatment. Accordingly, the present invention is also useful for a device in which the physically damaged layer is formed through blasting treatment.

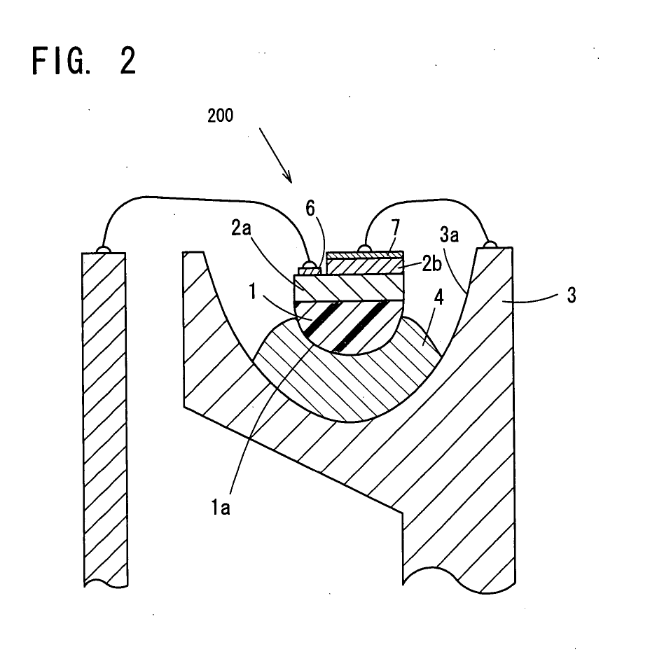

FIG. 2 is a sectional view of a face-up type light-emitting diode 200 in the second embodiment of the present invention. As shown in FIG. 2, the light-emitting diode 200 has structure as in a well-known face-up type light-emitting diode, and the back surface 1a of a semiconductor crystal substrate 1 made of undoped GaN bulk crystal is physically formed through polishing treatment, laser treatment and blasting treatment and then finished through dry-etching treatment. The polishing treatment is, as in the first embodiment, carried out in order to reduce thickness of the semiconductor crystal substrate 1. And the laser treatment is carried out in order to form a V-shaped groove for dividing the wafer and a proper R (roundness) on the back surface of the semiconductor crystal substrate 1. The blasting treatment is carried out in order to remove a fused and re-solidified material and a fused, scattered and re-solidified material and to provide a proper R (roundness). And the dry-etching treatment is, of course, carried out in order to remove the physically damaged layer left on the physically processed plane which is shaped through blasting treatment as in the first embodiment.

The sign 6 in FIG. 2 represents a negative electrode formed on an n-type semiconductor 2a and the sign 7 represents a positive electrode formed on an p-type semiconductor layer 2b. The positive electrode 7 is preferably a light-transparent electrode. On a lead frame 3, a reflection plane 3a formed almost in a rotation shape of secondary curve whose plane is formed almost in a mirror plane. The semiconductor crystal substrate 1 is adhered at the center of the inside bottom plane of the reflection plane 3a by a light-transparent adhesive 4. The light-transparent adhesive 4 may be preferably made of a transparent material as much as possible so as to improve external quantum efficiency. A tilt angle of a tilt plane 1a in the light-emitting diode 200 may preferably be arranged optimally in accordance with the value of the refractive index of the light-transparent adhesive 4. Alternatively, the tilt angle of the tilt plane 1a is determined first and then the material of the light-transparent adhesive 4 may be determined considering each condition such as refractive index.

In the light-emitting diode 200, luminous extracting efficiency of the back surface and the sidewalls of the semiconductor crystal substrate 1 having the tilt plane 1a is remarkably large owing to the actions and effects of the present invention. As a result, the face-up type LED (semiconductor light-emitting device) may also provide larger external quantum efficiency compared with the conventional device.

In short, the present invention can also be applied to a face-up type light-emitting diode.

### Third Embodiment

In the first embodiment, the taper part is formed at the semiconductor crystal substrate 102. Alternatively, the taper part for extracting light may be formed at the sidewall of each semiconductor layer (103-107) deposited through crystal growth to face to the surface of the wafer. The taper part deposited on formed on the side wall near the surface of semiconductor layers functioning as a device also contributes to improve luminous extracting efficiency and external quantum efficiency. A similar taper part tends to be formed at the surface of the wafer when a V-shaped groove for dividing chip is formed on the surface of the wafer. These taper parts can be formed by using, for example, a dicing cutter. And the etching treatment (finishing treatment) is useful for each of thus-obtained taper parts.

Such characteristics are explained in the third embodiment.

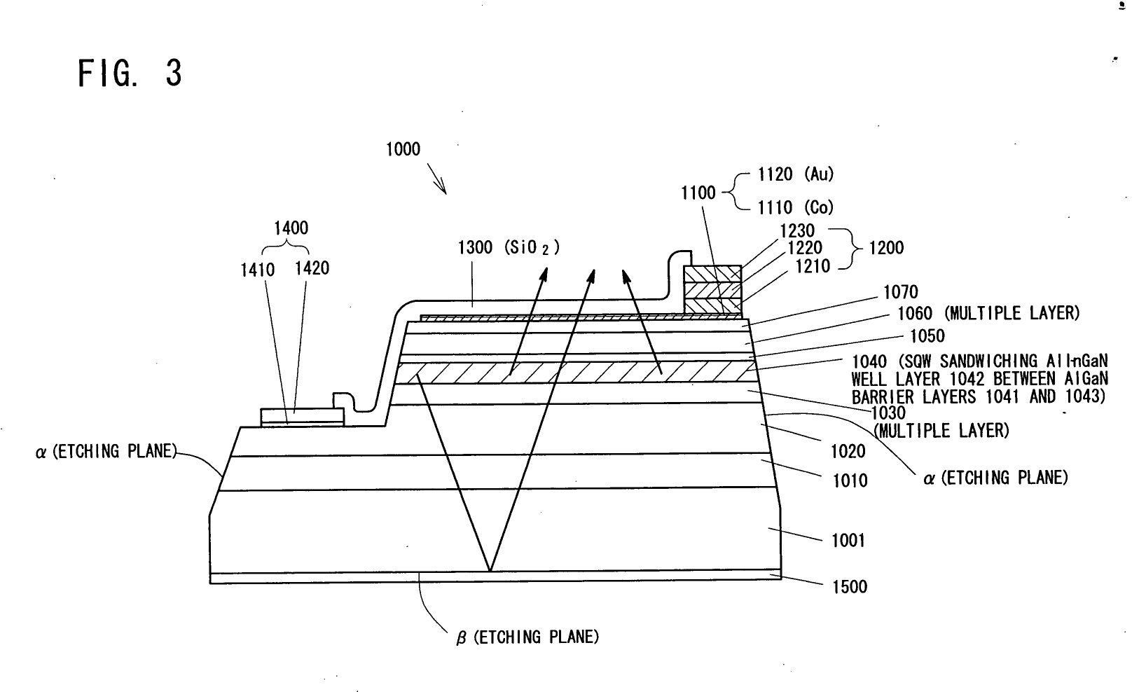

FIG. 3 is a sectional view of a face-up type light-emitting diode 1000 in the third embodiment of the present invention. The light-emitting diode 1000 comprises a sapphire substrate 1001 which is polished until its thickness becomes about 100 μm after forming a protection film 1300.

About 0.5 μm in thickness of aluminum nitride (AlN) single crystal layer 1011 is formed on the sapphire substrate 1001, and about 1.5 μm in thickness of silicon (Si) doped Al_{0.12}Ga0.88N n-type contact layer 1020 having electron concentration of 5×10¹⁸/cm³ is formed thereon.

About 100 nm in thickness of silicon (Si) doped n-type clad layer 1030 which has electron concentration of 5×10¹⁹/cm³ and has multiple-layer structure comprising 38 pairs of about 1.5 nm in thickness of Al_{0.15}Ga_{0.85}N layer 1031 and about 1.5 nm in thickness of Al_{0.04}Ga_{0.96}N layer 1032 is formed on the n-type contact layer 1020.

An emission layer 1040 which has single quantum well structure and mainly emits ultraviolet light is formed on the n-type clad layer 1030. The emission layer 1040 having single quantum well (SQW) structure is formed by depositing about 25 nm in thickness of undoped Al_{0.13}Ga_{0.87}N barrier layer 1041, about 2 nm in thickness of undoped Al_{0.005}In_{0.045}Ga_{0.95}N well layer 1042, and about 15 nm in thickness of undoped Al_{0.13}Ga_{0.87}N barrier layer 1043 in sequence.

About 40 nm in thickness of magnesium (Mg) doped Al_{0.16}Ga_{0.84}N p-type block layer 1050 having hole concentration of 5×10¹⁷/cm³ is formed on the emission layer 1040. About 90 nm in thickness of magnesium (Mg) doped p-type clad layer 1060 which has hole concentration of 5×10¹⁷/cm³ and comprises 30 pairs in total comprising about 1.5 nm in thickness of Al_{0.12}Ga_{0.88}N layer 1061 and about 1.5 nm in thickness of Al_{0.03}Ga_{0.97}N layer 1062 is formed on the p-type block layer 1050. About 30 nm in thickness of magnesium (Mg) doped AlGaN p-type contact layer 1070 having hole concentration of 1×10¹⁸/cm³ is formed on the p-type clad layer 1060.

A light-transparent thin film positive electrode 1100 is formed on the p-type contact layer 1070 through metal deposition and a negative electrode 1400 is formed on the n-type contact layer 1020. The light-transparent thin film positive electrode 1100 comprises about 1.5 nm in thickness of first layer 1110 which is made of cobalt (Co) and directly contacts to the p-type contact layer 1070 and about 6 nm in thickness of second layer 1120 which is made of gold (Au) and contacts to the cobalt film.

A thick film positive electrode 1200 is formed on the light-transparent thin film positive electrode 1100 by depositing about 18 nm in thickness of first layer 1210 made of vanadium (V), about 15 μm in thickness of second layer 1220 made of gold (Au), and about 10 nm in thickness of third layer 1230 made of aluminum (Al) in sequence.

The negative electrode 1400 having multiple-layer structure is formed by depositing about 18 nm in thickness of first layer 1410 made of vanadium (V) and about 100 nm in thickness of second layer 1420 made of aluminum (Al) on an exposed portion of the n-type contact layer 1020.

And a protection film 1300 made of an SiO₂ film is formed on the uppermost part of the wafer. On the bottom plane (etching plane β) of the sapphire substrate 1001 which is treated through etching, about 500 nm in thickness of reflection metal layer 1500 made of aluminum (Al) is formed through metal deposition. Alternatively, the reflection metal layer 1500 may comprises a metal such as Rh, Ti, and W, and also a nitride compound such as TiN and HfN.

An etching plane α in a taper shape is formed at each sidewall of the wafer as shown in FIG. 3. When a V-shaped groove for dividing the wafer is formed by using a dicing cutter, a taper part (grinded plane) is formed at the sidewalls of the wafer including the semiconductor crystal layer and the etching plane α is obtained by finishing the taper part through dry-etching treatment. Because the physically damaged layer which is formed in the V-shaped groove forming process and is left at the taper part (grinded plane) is removed from the etching plane α, absorption of ultraviolet light can be effectively reduced. As a result, the etching plane α treated by dry-etching greatly contributes to extract light toward upside of the wafer.

The etching plane β (the bottom surface of the sapphire substrate 1001) is obtained by further dry-etching the back surface of the wafer (polished plane) which is exposed through polishing treatment. Because the physically damaged layer which is formed and left at the back surface of the wafer (grinded plane) after grinding treatment is removed from the etching plane β, absorption of ultraviolet light can be effectively reduced. As a result, reflectivity of the reflection metal layer 1500 can be improved effectively. Accordingly, the etching plane β treated by dry-etching greatly contributes to extract light toward upside of the wafer.

In the wafer of this embodiment, a band gap of each semiconductor crystal layer is maintained as large as possible by optimizing aluminum composition ratio of each semiconductor crystal layer. By employing such structure, light in near-ultraviolet region emitted by the emission layer can be effectively restrained from being absorbed in the semiconductor crystal layers except for the emission layer. Accordingly, arranging band gap of each layer as in this embodiment may also contribute to improving external quantum efficiency of the light-emitting diode 100.

### Fourth Embodiment

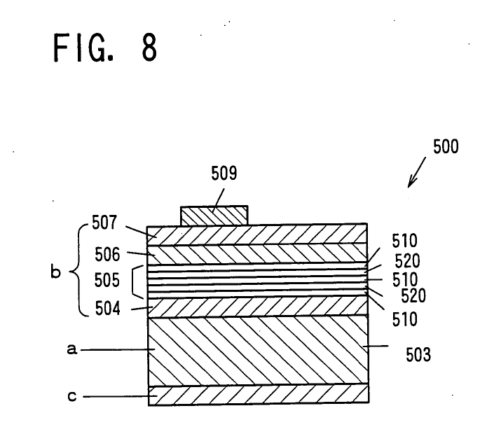

FIG. 8 is a sectional view of the main portion of a light-emitting diode 500 of the fifth embodiment of the present invention. As shown in FIG. 8, a semiconductor substrate a is doped with silicon (Si) as an impurity and its doping concentration is about 4×10¹⁸/cm³. Owing to its function in the light-emitting diode 500, the semiconductor substrate a is also referred to as a n-type contact layer 503 hereinafter.

A crystal growth layer b comprises a Group III nitride compound semiconductor having multiple-layer structure. The surface of the semiconductor substrate a comprising an n-type gallium nitride (GaN) contributes to crystal growth of the crystal growth layer b. The opposite surface of the semiconductor substrate a (hereinafter referred to as a back surface or a polished plane) is polished and dry-etched, and a negative electrode (n-electrode c) is formed thereon.

On the semiconductor substrate a (n-type contact layer 503), 105 Å in thickness of undoped GaN n-type clad layer 504 (low-carrier concentration layer) is formed. An active layer 505 of MQW structure comprising 5 layers in total is formed thereon. In the active layer 505, about 35 Å in thickness of In_{0.30}Ga_{0.70}N well layer 510 and about 70 Å in thickness of GaN barrier layer 520 are deposited alternately. About 50 nm in thickness of Mg-doped p-type Al_{0.15}Ga_{0.85}N is formed as a p-type clad layer 506 on the active layer 505. And about 100 nm in thickness of Mg-doped p-type GaN is formed as a p-type contact layer 507 on the p-type clad layer 506.

On the p-type contact layer 507, a light-transparent positive electrode (p-electrode 509) is formed by metal deposition. The p-electrode 509 comprises about 40 Å in thickness of cobalt (Co) which directly contacts to the p-type contact layer 507 and about 60 Å in thickness of gold which contacts to the Co layer.

The n-electrode c is formed by depositing about 200 Å in thickness of vanadium (V) and about 1.8 μm in thickness of aluminum (Al) or an alloy including Al in sequence on the back surface (etched plane) of the substrate. Thickness of the n-electrode c is arranged larger in order to reflect light toward upside sufficiently.

Next, a method for manufacturing the light-emitting diode 500 is explained hereinafter. Processes and materials employed in this embodiment are as same as those in the third embodiment of the present invention.

The semiconductor substrate a made of single crystal GaN was placed on a susceptor in a reaction chamber for the MOVPE treatment after its main surface ‘a’ was cleaned by an organic washing solvent and heat treatment. Thickness of the semiconductor substrate a was about 400 μm. Then the semiconductor substrate a was baked at about 1150° C. under H₂ vapor fed at 2 liter/min. into the chamber for 30 minutes under normal atmospheric pressure.

(Growth of the N-Type Clad Layer 504)

105 Å in thickness of undoped GaN was formed as the n-type clad layer 504 (low carrier concentration layer) under conditions controlled by keeping the temperature of the semiconductor substrate a at 1150° C., and concurrently supplying H₂, NH₃, and TMG at a flow rate of 20 liter/min., 10 liter/min., and 1.7×10⁻⁴ mol/min., respectively.

(Growth of the Active Layer 505)

After forming the n-type clad layer 504, the active layer 505 of MQW structure (shown in FIG. 8), comprising 5 layers in total, was formed.

First, about 35 Å in thickness of In_{0.30}Ga_{0.70}N well layer 510 was formed on the n-type clad layer 504 under conditions controlled by lowering the temperature of the semiconductor substrate a to 730° C., changing carrier gas from H₂ to N₂, keeping the supplying amount of the carrier gas N₂ and NH₃, and concurrently supplying TMG and TMI at a flow rate of 3.1×10⁻⁶ mol/min. and 0.7×10⁻⁶ mol/min., respectively.

Next, about 70 Å in thickness of GaN barrier layer 520 was formed on the well layer 510 under conditions controlled by raising the temperature of the semiconductor substrate a to 885° C., and concurrently supplying N₂, NH₃, and TMG at a flow rate of 20 liter/min., 10 liter/min., and 1.2×10⁻⁵ mol/min., respectively.

By repeating these processes, the well layer 510 and the barrier layer 520 were formed alternately and the active layer 505 comprising 5 layers in total (the well layer 510, the barrier layer 520, the well layer 510, the barrier layer 520, and the last well layer 510) was obtained.

(Crystal Growth of the P-Type Clad Layer 506)

Then magnesium (Mg) doped p-type Al_{0.15}Ga_{0.85}N having thickness of about 200 Å and Mg concentration of 5×10¹⁹/cm³ was formed as a p-type clad layer 506 under conditions controlled by raising the temperature of the semiconductor substrate a to 890° C. and concurrently supplying N₂, TMG, TMA, and CP₂Mg at a flow rate of 10 liter/min., 1.6×10⁻⁵ mol/min., 6×10⁻⁶ mol/min., and 4×10⁻⁷ mol/min., respectively.

(Crystal Growth of the P-Type Contact Layer 507)

Then Mg-doped p-type GaN having thickness of about 85 nm and Mg concentration of 5×10¹⁹/cm³ was formed as a p-type contact layer 507 under conditions controlled by raising the temperature of the semiconductor substrate a to 1000° C., changing the carrier gas to H₂ again, and concurrently supplying H₂, NH₃, TMG, and CP₂Mg at a flow rate of 20 liter/min., 10 liter/min., 1.2×10⁻⁴ mol/min., and 2×10⁻⁵ mol/min., respectively.

The processes described above are the crystal growth process of each semiconductor layer comprising a Group III nitride compound semiconductor.

(Forming the P-Electrode 509)

After the crystal growth processes described above, a photoresist layer was then formed on the surface of the p-type contact layer 507. The portion of the photoresist layer above the electrode forming part of the p-type contact layer 507 was then removed by patterning using photolithography to form a window. In short, only a portion of the p-type contact layer 507 for forming the p-electrode 509 was exposed. After establishing a high vacuum of less than 10⁻⁴ Pa vacuum order, about 40 Å in thickness of Co was deposited on the exposed portion of the p-type contact layer 507, and 60 Å in thickness of Au was deposited on the Co. The sample was then removed from the vacuum evaporation equipment and Co and Au laminated on the photoresist layer were removed by a lift-off process. Accordingly, the light-transparent p-electrode 509 adhering to the p-type contact layer 507 was formed.

(Polishing Treatment)

Next, the back surface of the semiconductor substrate a was polished by using a polishing machine. Diameter of grain of the slurry employed in this polishing treatment was 9 μm, and the polishing treatment was carried out until thickness of the semiconductor substrate a decreased from 400 μm to 150 μm. Then the wafer was washed and dried. Diameter of grain of the slurry employed in the polishing treatment may preferably in a range from 0.5 μm to 15 μm. When the diameter of grain of the slurry is too big, thickness of the damaged layer tends to become too large, which is not desirable. When the diameter of grain of the slurry is too small, the polishing treatment tends to take too much time, which is not desirable. More preferably, the diameter of grain of the slurry is in a range from 1 μm to 9 μm.

(Etching Treatment)

Next, the back surface (the polished plane) of the semiconductor substrate a polished in the polishing treatment was dry-etched to the depth of about 2 μm. This dry-etching treatment removed at least most of the damaged layer which was generated in the polishing treatment. Any of the following equipments can be employed in this dry-etching treatment:

(a) RIE equipment

(b) ICP equipment

For example, the dry-etching disclosed in Japanese Patent Application Laid-open No. H8-274081 may be referred to as a standard of dry-etching treatment.

(Forming the N-Electrode C)

Next, a photoresist layer was formed on the entire back surface of the semiconductor substrate a. The portion of the photoresist layer above the predetermined part of the n-type contact layer 503 was then removed by patterning using photolithography to form a window. In short, only a portion of the n-type contact layer 503 was exposed. After establishing a high vacuum of less than 10⁻⁴ Pa vacuum order, about 200 Å in thickness of vanadium (V) was deposited on the exposed portion of the n-type contact layer 503, and 1.8 μm in thickness of Al was deposited on the V. Then the photoresist layer was removed and the n-electrode c adhering to the semiconductor substrate a (n-type contact layer 503) was obtained.

(Alloying Treatment)

Next, the chamber in which the resultant sample was placed was evacuated by use of a vacuum pump, and subsequently O₂ gas was fed to the chamber, to thereby regulate the pressure of the chamber to 3 Pa. Thereafter, the temperature of the chamber was maintained at about 550° C., and the sample was heated for about three minutes, to thereby lower the resistances of the p-type contact layer 507 and the p-type clad layer 506, as well as to perform alloying of the contact layer 507 and the p-electrode 509 and alloying of the semiconductor substrate a and the n-electrode c. Thus, the electrodes (the n-electrode c and the p-electrode 509) can be connected to each semiconductor layer on which both electrodes were deposited more firmly.

Half cutting treatment or scribing treatment was carried out to the surface of the wafer, and the semiconductor wafer was divided into each chip through breaking process. Each of these processes may be carried out according to a well-known prior art. For example, the dividing technique disclosed in the Japanese Patent Application Laid-open No. 2001-284642 may be referred to as a standard of dividing process.

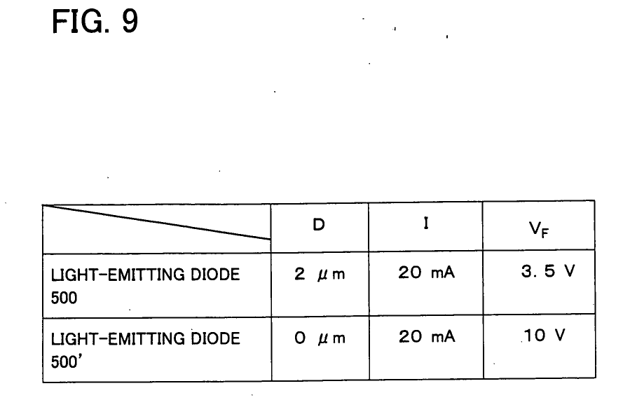

FIG. 9 is a table showing each driving voltage V_{F} of the light-emitting diode 500 of this embodiment and its modified example (light-emitting diode 500′). The light-emitting diode 500′ has the same structure as shown in FIG. 8. The light-emitting diode 500′ has the same structure as the light-emitting diode 500 except for that dry-etching treatment for dry-etching the polished plane of the semiconductor substrate a is not carried out in a method for manufacturing the light-emitting diode 500′. In short, depth D of dry-etching the light-emitting diode 500′ is 0 μm as shown in FIG. 9.

In FIG. 9, “I” represents driving electric current flown between the positive electrode and the negative electrode of the device, and it shows electric current value which is needed for excellent luminous output of each light-emitting diode. As shown in the table of FIG. 9, while driving voltage V_{F} of the light-emitting diode 500 to which 2 μm in depth of dry-etching is carried out is 3.5 v, driving voltage V_{F} of the light-emitting diode 500′ to which dry-etching is not carried out is 10 v, which is larger than the driving voltage of the light-emitting diode 500 by 6.5 v.

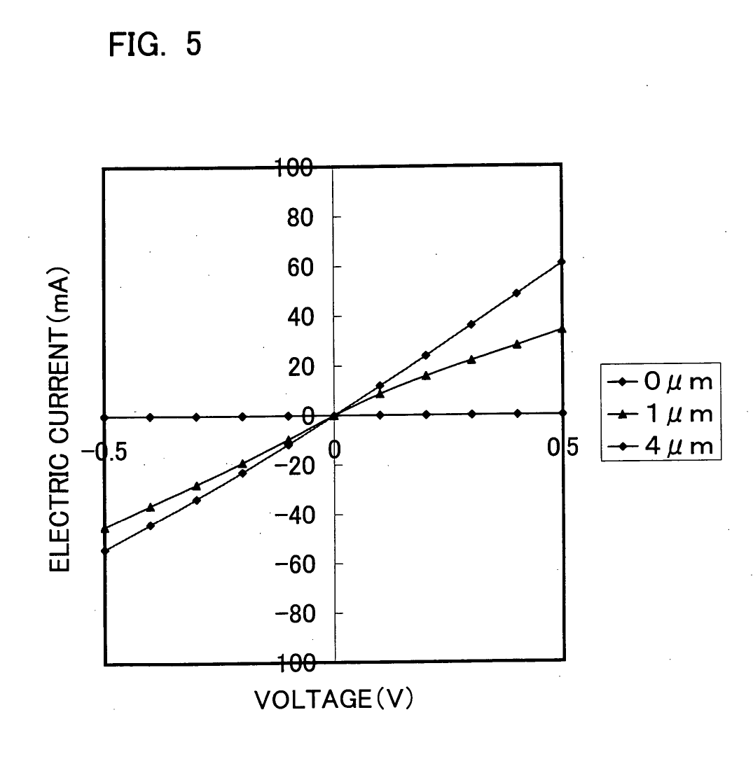

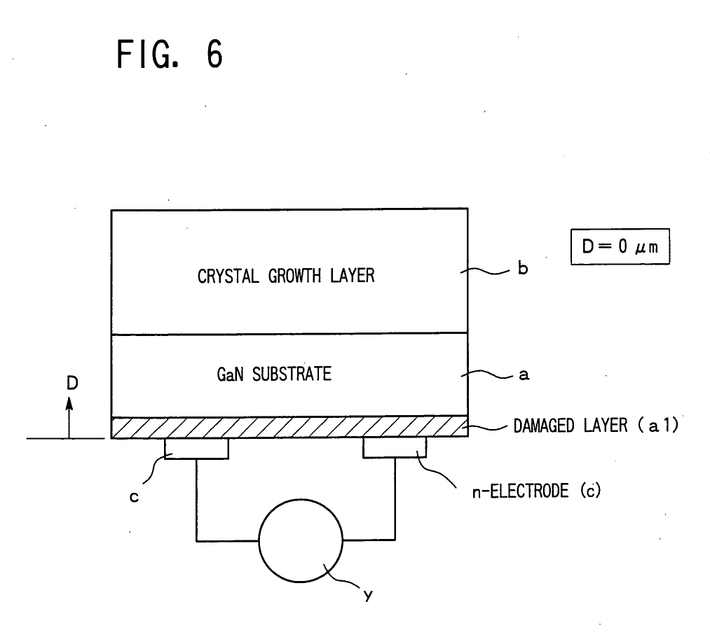

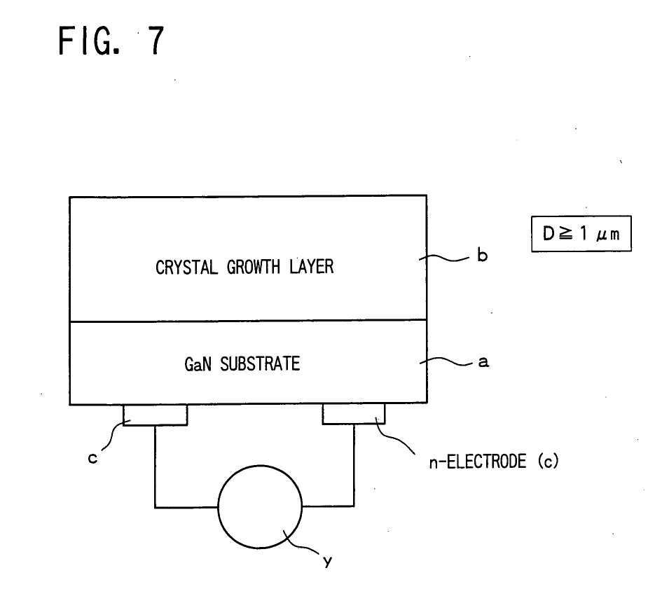

According to the result described above, when the n-electrode c is formed on the back surface of the semiconductor substrate a having conductivity as in the light-emitting diode 500 in FIG. 8, for example, preferable depth D of dry-etching can be figured out to be about 2 μm. That can be also explained in actions and effects shown in FIGS. 5, 6, and 7 described above.

Although it depends on each condition such as the size of grain of slurry, strength of frictional force and pressure, and composition ratio of the substrate, in order to provide excellent ohmic characteristic between the semiconductor substrate and the electrode, experiments show that the optimum depth D of dry-etching may be in a range from 1 μm to 8 μm. When the depth D of dry-etching is within this range, time for carrying out both polishing treatment and dry-etching treatment can be reduced to minimum, and that is desirable for productivity of the device.

In the fourth embodiment, an n-type AlₓGa₁₋ₓN (0≦x≦1) is preferable to form the semiconductor substrate a. Alternatively, the semiconductor substrate a may be made of other Group III nitride compound semiconductor. In the fourth embodiment, Si is doped as an n-type impurity into the semiconductor substrate a. Alternatively, n-type impurity to be doped into the semiconductor substrate a may not be limited to Si.

In the fourth embodiment, a single gallium nitride crystal (n-type bulk GaN) is used to form the semiconductor substrate a. Alternatively, the semiconductor substrate a is not necessarily have single-layer structure. For example, in order to form the semiconductor substrate a to have the structure shown in FIG. 8, an n-type AlₓGa₁₋ₓN (0≦x≦1) which has a thickness of 150 μm or more and remains as an appropriate n-type contact layer 503 may be enough. Because the portion whose thickness is 150 μm or more is removed in the polishing process, it may have an arbitral structure. Accordingly, a base layer is formed on the silicon substrate and then the n-type GaN layer may be grown thereon. At that time, the silicon substrate and the base layer may be removed through polishing treatment and it is enough to leave about 150 μm in thickness of the n-type AlₓGa₁₋ₓN (0≦x≦1).

Here, thickness of the n-type contact layer to be left is not necessarily limited to 150 μm described above. Alternatively, thickness of the n-type contact layer to be left may be arbitral if it is in a range from 50 μm to 300 μm. Thickness of the semiconductor substrate a before carrying out polishing process is preferably in a range from 250 μm to 500 μm. More preferably, its thickness may be in a range from 300 μm to 400 μm. When the thickness is too large, polishing process takes too much time, and that is not desirable. When the thickness is too small, the semiconductor wafer tends to be damaged while it is handled, and that is not desirable.

In the fourth embodiment, the p-electrode 509 is formed before polishing process is carried out. Alternatively, the p-electrode 509 may be formed through similar process of forming the n-electrode c, or may be formed after etching process.

Alternatively, the n-electrode c may be formed after carrying out heat treatment (alloying process of the p-electrode 509). At that time, heat treatment is not carried out to the n-electrode c deposited on the semiconductor substrate a, and practically the n-electrode is not alloyed.

In the fourth embodiment, the p-electrode 509 has light-transparency. Alternatively, the n-electrode c may have light-transparency.

In the fourth embodiment, the active layer has MQW structure. Alternatively, the active layer may have SQW structure or single-layer structure which does not have quantum-well structure.

### Fifth Embodiment

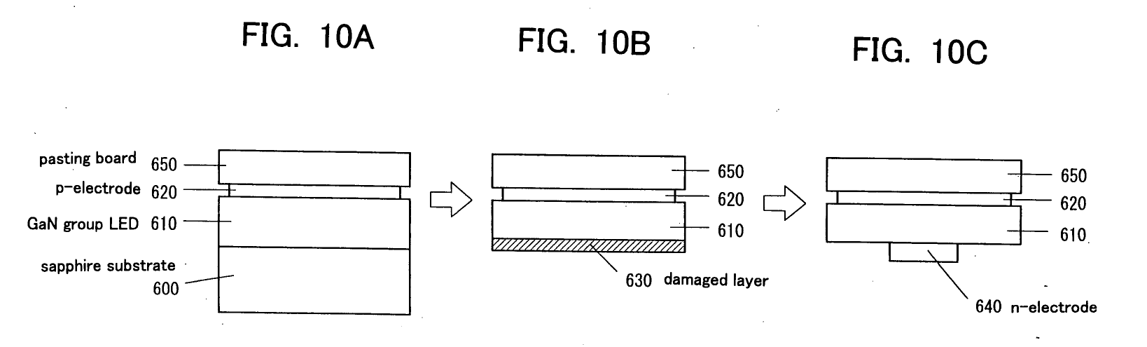

Other embodiment of the present invention will next be described. A light-emitting diode 610 which comprises plural layers made of group III nitride compound semiconductor formed on a sapphire substrate 600 is formed as shown in FIG. 10A. A p-electrode 620 is formed on the light-emitting diode 610, and a pasting board 650 is adjusted to the p-electrode 620. Next, as shown in FIG. 10B, the sapphire substrate 600 is polished and removed by using the pasting board 650 as a holding member hold-back material??). Then a damage layer 630 is formed in the Group III nitride compound semiconductor layer, which is the bottom layer in the light-emitting diode. The damage layer 630 is etched in a process similar to that in the fourth embodiment. After the etching treatment, an n-electrode 640 is formed on the etched Group III nitride compound semiconductor layer. The pasting board 650 functions as a holding member while the sapphire substrate 600 is polished. As a product, the pasting board 650 can be used as a heat sink of the light-emitting diode 610, a metal reflection plate which reflects light to the n-electrode 640 side, or a fixing member of the light-emitting diode 610. Further, the pasting board 650 can be exfoliated after polishing process of the sapphire substrate 600. In the fifth embodiment, n-layer is deposited on the sapphire substrate 600 before the p-layer. Alternatively, the p-layer may be deposited before the n-layer. The p-layer deposited on the sapphire substrate 600 before depositing the n-layer can be activated by carrying out heat treatment after polishing the sapphire substrate 600.

The present invention can be applied to manufacture such light-emitting diode.

The present invention can be widely applied to a semiconductor device in which an electrode is formed directly on a semiconductor substrate. Such a semiconductor device may include a light-emitting semiconductor laser such as a semiconductor laser (LD) and a light-emitting diode (LED), and also include a light-receiving device and a pressure sensor. The present invention may not restrict concrete function and structure of those semiconductor devices, and that enables to apply the present invention in remarkably large field.

### INDUSTRIAL APPLICABILITY

The present invention can be applied to a light-emitting diode having comparatively shorter wavelength and emission region at least a portion of whose luminous spectrum is less than 470 nm. Accordingly, the present invention can also be applied to a luminous device having emission region in visible light region.

Further, owing to its actions and effects, the present invention can also be applied to a light-receiving semiconductor device.

The present invention may not restrict any condition such as crystal growth condition, composition, and deposition structure of those semiconductor devices.

The present invention is also very useful to a short-wavelength luminous device whose luminous wavelength is in ultraviolet region. Such short-wavelength luminous device may be applied in photochemistry field using photoexcitation catalyst, in illumination filed used to excite phosphor, or in bio-related field represented by a light trap, and it can be applied to, for example, a black-light lamp consisted in a fluorescent lamp.

While the present invention has been described with reference to the above embodiments, the present invention is not limited thereto, but may be modified as appropriate without departing from the spirit of the invention.

The entire disclosures and contents of Japanese Patent Application Nos. 2004-112796 and 2003-202240, from which the present invention claims convention priority, are incorporated herein by reference.

1. A method for fabricating a light-emitting diode of a surface emitting type in which a semiconductor layer is deposited on a crystal growth plane of a crystal growth substrate, comprising steps of:
a shaping process for forming at least one of an output plane and a reflection plane which contributes to luminous output of the device through polishing treatment, dicing treatment, and blasting treatment from the back surface of said crystal growth substrate; and
a finishing process for finishing said at least one of output plane and said reflection plane by further carrying out etching treatment.

2. A method for fabricating a light-emitting diode according to claim 1, wherein said shaping process comprises a taper part forming process for forming a taper plane, which inclines to said crystal growth plane of said crystal growth substrate, at least as a portion of said output plane or at least as a portion of said reflection plane.

3. A method for fabricating a light-emitting diode according to claim 2, wherein at least a portion of said taper part forming process comprises of a process for forming an approximately V-shaped dividing groove which divides a semiconductor wafer comprising plural light-emitting diodes into each of said light-emitting diode.

4. A method for fabricating a light-emitting diode according to claim 1, wherein peak luminous wavelength of said light-emitting diode is less than 470 nm.

5. A method for fabricating a light-emitting diode according to claim 1, wherein said crystal growth substrate is formed by using AlₓGa₁₋ₓN (0≦x≦1) or silicon carbide (SiC).

6. A light-emitting diode of a surface emitting type in which a semiconductor layer is deposited on a crystal growth plane of a crystal growth substrate, wherein
said crystal growth substrate comprises at least one of an output plane and a reflection plane which contributes to luminous output of the device through a physical shaping process such as polishing treatment, dicing treatment and blasting treatment, and
a physically damaged layer which is formed on the surface of at least one of said output plane and said reflection plane and remains owing to friction and shock generated in said shaping process is removed.

7. A light-emitting diode according to claim 6, wherein a metal layer which has light-transparency to transmit light to the luminous extracting side of said device is formed on said output plane.

8. A light-emitting diode according to claim 6, wherein a metal layer which reflects light to the luminous extracting side of said device is formed on said reflection plane.

9. A light-emitting diode according to claim 6, wherein said crystal growth substrate is formed by using AlₓGa₁₋ₓN (0≦x≦1) or silicon carbide (SiC).

10. A light-emitting diode according to claim 6, wherein a taper plane which inclines to said crystal growth plane of said crystal growth substrate is formed at least as a portion of at least one of output plane or at least as a portion of said reflection plane.

11. A light-emitting diode of a surface emitting type in which a semiconductor layer is deposited on a crystal growth plane of a crystal growth substrate, comprising:
a taper plane which inclines to said crystal growth plane of said crystal growth substrate which is formed at least at a portion of the sidewall of said light-emitting diode,
wherein said taper plane is exposed to the surface side of said light-emitting diode at which a semiconductor crystal layer and a positive electrode are formed, and
a physically damaged layer which is formed on the surface of said taper plane and remains owing to friction and shock generated in said taper part is removed.

12. A light-emitting diode according to claim 10 which is fabricated by dividing a semiconductor wafer comprising plural light-emitting diodes into each of said light-emitting diode, comprising:
a taper plane at least at a portion of the sidewall of said light-emitting diode,
wherein said taper plane is a portion of the plane of an approximately V-shaped dividing groove which divides the semiconductor wafer into each of said light-emitting diode.

13. A light-emitting diode according to claim 6, wherein the peak luminous wavelength of said light-emitting diode is less than 470 nm.

14. A method for forming an electrode in which an electrode is formed on a polished plane of a conductive semiconductor substrate which comprises a Group III nitride compound semiconductor and has already been polished comprising a step of:
etching process for carrying out dry-etching treatment to said polished plane of said semiconductor substrate before electrode forming process for forming an electrode on said polished plane of said semiconductor substrate.

15. A method for forming an electrode according to claim 14, wherein said semiconductor substrate is formed by using an n-type AlₓGa₁₋ₓN (0≦x≦1).

16. A method for forming an electrode according to claim 14, wherein depth of removing said polished plane through said dry-etching treatment is in a range from 0.1 μm to 15 μm.

17. A method for forming an electrode according to claim 16, wherein depth of removing said polished plane through said dry-etching treatment is in a range from 0.2 μm to 8 μm.

18. A method for fabricating a light-emitting diode according to claim 2, wherein peak luminous wavelength of said light-emitting diode is less than 470 nm.

19. A method for fabricating a light-emitting diode according to claim 2, wherein said crystal growth substrate is formed by using AlₓGa₁₋ₓN (0≦x≦1) or silicon carbide (SiC).

20. A light-emitting diode according to claim 7, wherein a metal layer which reflects light to the luminous extracting side of said device is formed on said reflection plane.
